(19) United States
(12) Patent Application Publication
(10) Pub. No.: US 2012/0085885 A1
(43) Pub. Date: Apr. 12, 2012

(54) TILT FOOT MECHANISM AND PROJECTION DISPLAY INCLUDING THE MECHANISM

(76) Inventor: Qing Song, Tokyo (JP)

(21) Appl. No.: 13/378,350

(22) PCT Filed: Jul. 7, 2009
(86) PCT No.: PCT/JP09/63052

§ 371 Date: Dec. 14, 2011

(51) Int. Cl. H05K 7/00; F16M 11/24

(52) U.S. Cl. 248/676; 248/372.1

(57) ABSTRACT

A tilt foot mechanism adjusts a tilt angle of a case by adjusting a length of a protruding portion of a foot protruding from the case, and the tilt foot mechanism includes: a base into which the foot is inserted, wherein the base guides a protruding direction of the inserted foot; and a lever that is assembled with the base and that fixes the foot to the base by being biased to the foot, wherein the lever is rotatable, and the lever is maintained in astute of fixing the foot by a biasing force in a first direction, and the lever releases fixing of the foot by being rotated in a second direction different from the first direction, wherein a first guiding portion and a second guiding portion are provided at the base, wherein the first guiding portion and the second guiding portion define a rotation center of the lever when the first guiding portion and the second guiding portion are assembled with the base, and wherein a first guided portion, a second guided portion, and an engaging portion are provided at the lever, wherein the first guided portion and the second guided portion slide along the first guiding portion and the second guiding portion, and wherein the engaging portion remains in a state of being assembled with the base.

### TECHNICAL FIELD

The present invention relates to a tilt foot mechanism and a projection display including this mechanism.

### BACKGROUND ART

Some of projection displays include a tilt foot mechanism that enables adjustment to the projection angle, which is an angle of an optical axis of light to be projected with respect to a horizontal surface, according to the height of a screen, The tilt foot mechanism includes a rod-like foot. The foot is generally inserted through the bottom surface of the case of the projection display.

The foot inserted through the case is fixed to the case by being engaged with a locking mechanism provided in the case. Additionally, when engagement of the locking mechanism with the foot is released, the foot can move in the case in a longitudinal direction thereof. In other words, a length of a protruding portion of the foot, which is the length of the foot below the bottom surface of the case, can be changed. The foot is fixed to the case again by the locking mechanism after the length of the protruding portion is adjusted.

The foot is, for example, provided at one place of a front side of the case. In this case, when the protruding portion of the foot is long, the front of the case is high, and when the protruding portion of the foot is short, the front of the case is low. Namely, since tilt (a tilt angle) to a horizontal surface of the case changes when the length of the protruding portion of the foot is changed, a projection angle of the projection display changes. Accordingly, a user can adjust the projection angle of the projection display by changing the length of the protruding portion of the foot.

Such a tilt foot mechanism is described in Patent Literature 1. In the tilt foot mechanism described in Patent Literature 1, provided are: a foot inserted through a case; a lever that locks the foot so that a length of a protruding portion of the foot protruding from the case may not be changed; and a supporting member that supports the lever so that the lever may not be detached from the case. The lever can be rotated with respect to the case, and a locking state/non-locking state of the foot is switched by the lever according to a rotating state of the lever. The lever is configured so that the locking state thereof may be maintained by a spring.

### CITATION LIST

### Patent Literature

Patent Literature 1: JP2001-356414A

### SUMMARY OF INVENTION

### Technical Problem

The tilt foot mechanism shown in Patent Literature 1 requires the lever, the supporting member that supports the lever, the foot, the case, and the spring, and thus it is a mechanism that has a large number of parts. If the number of parts can be reduced, the number of steps for assembly will also be reduced. This enables a reduction in the manufacturing cost of the tilt foot mechanism.

Consequently, an object of the present invention is to provide a tilt foot mechanism that has a new structure with a small number of parts, and a projection display that includes this mechanism.

### Solution to Problem

In order to achieve the above-described object, a tilt foot mechanism of the present invention is the tilt foot mechanism that adjusts a tilt angle of a case by adjusting a length of a protruding portion of a foot protruding from the case, and the tilt foot mechanism includes: a base into which the foot is inserted, wherein the base guides a protruding direction of the inserted foot; and a lever that is assembled with the base and that fixes the foot to the base by being biased to the foot, wherein the lever is rotatable, and the lever is maintained in a state of fixing the foot by a biasing force in a first direction, and the lever releases fixing of the foot by being rotated in a second direction which is different from the first direction, wherein a first guiding portion and a second guiding portion are provided at the base, wherein the first guiding portion and the second guiding portion define a rotation center of the lever when the first guiding portion and the second guiding portion are assembled with the base, and a first guided portion, a second guided portion, and an engaging portion are provided at the lever, wherein the first guided portion and the second guided portion slide along the first guiding portion and the second guiding portion, and wherein the engaging portion remains in a state of being assembled with the base.

### Advantageous Effect of Invention

According to the present invention, the tilt foot mechanism of the new structure that has a small number of parts and the projection display including this mechanism can be provided.

### BRIEF DESCRIPTION OF DRAWINGS

FIG. 1 is an exploded perspective view of a tilt foot mechanism according to an exemplary embodiment.

FIG. 2 is a side view of the tilt foot mechanism shown in FIG. 1.

FIG. 3 is a side view of the tilt foot mechanism shown in FIG. 1.

FIG. 4 is a side view of the tilt foot mechanism shown in FIG. 1.

FIG. 5A is a side view of a lever of the tilt foot mechanism shown in FIG. 1.

FIG. 5B is a top view of the lever of the tilt foot mechanism shown in FIG. 1.

FIG. 5C is a rear view of the lever of the tilt foot mechanism shown in FIG. 1.

FIG. 6 is a side view showing a state of the tilt foot mechanism shown in FIG. 1 before a foot is attached thereto.

FIG. 7 is a side view of the tilt foot mechanism shown in FIG. 1.

FIG. 8 is a side view of the tilt foot mechanism shown in FIG. 1.

FIG. 9 is a view showing a rotating mechanism of the lever of the tilt foot mechanism shown in FIG. 1.

FIG. 10 is a view showing a modified example of the rotating mechanism of the lever of the tilt foot mechanism shown in FIG. 1.

FIG. 11A is a view showing the rotating mechanism of the lever of the tilt foot mechanism shown in FIG. 1.

FIG. 11B is a view showing the rotating mechanism of lever of the tilt foot mechanism shown in FIG. 1.

FIG. 12 is a view showing a modified example of the rotating mechanism of the lever of the tilt foot mechanism shown in FIG. 1.

FIG. 13 is a view showing a modified example of the rotating mechanism of the lever of the tilt foot mechanism shown in FIG. 1.

FIG. 14A is a side view of a projection display to which the tilt foot mechanism shown in FIG. 1 is applied.

FIG. 14B is a side view of the projection display to which the tilt foot mechanism shown in FIG. 1 is applied.

FIG. 15 is a perspective view showing the inside of the projection display to which the tilt foot mechanism shown in FIG. 1 is applied.

### DESCRIPTION OF EMBODIMENT

Next, an exemplary embodiment will be described with reference to drawings.

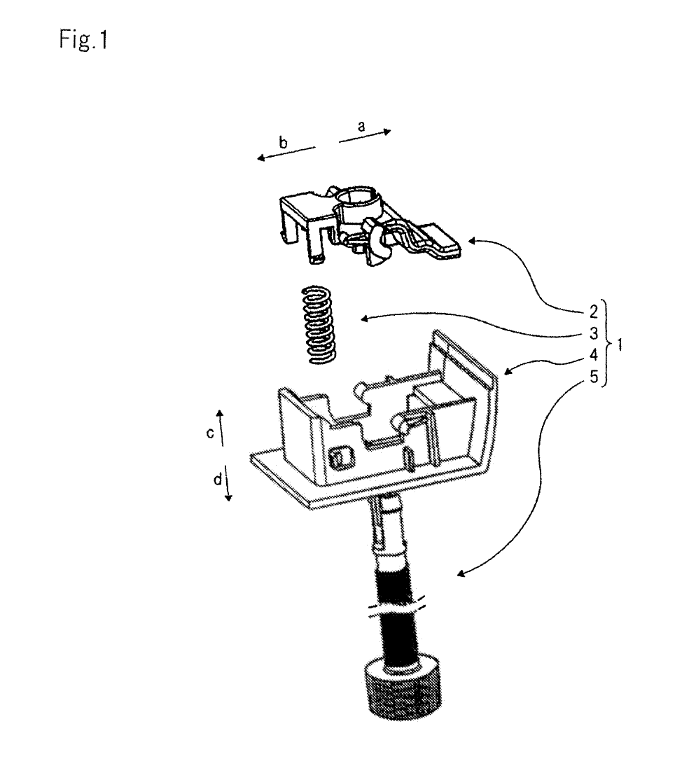

FIG. 1 is an exploded perspective view of a tilt foot mechanism according to an exemplary embodiment. Tilt foot mechanism 1 comprises four parts, i.e., lever 2, spring 3, base 4, and foot 5. Here, the direction of arrow a in FIG. 1 is defined as a forward direction, the direction of arrow b is a backward direction, the direction of arrow c is an upward direction, and the direction of arrow d is a downward direction.

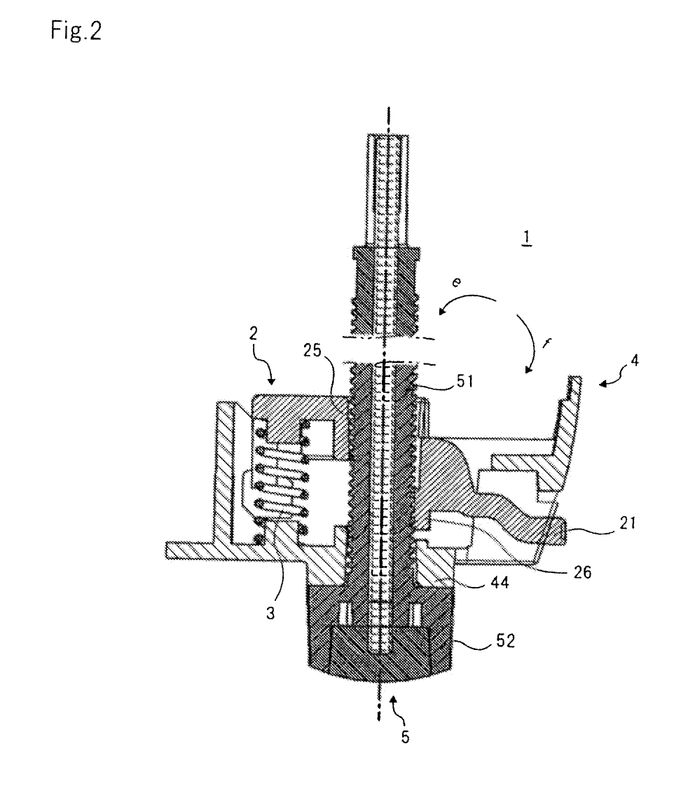

FIG. 2 is a side cross-sectional view showing a state where each part of tilt foot mechanism 1 is assembled with each other. Cylindrical portion 44 is provided at base 4, and partial cylindrical portion 25 is provided at lever 2. Cylindrical portion 44 and partial cylindrical portion 25 have a cylindrical shape and a shape formed by cutting out a portion of a cylindrical shape in a height direction, respectively, and curvatures thereof are set to be substantially the same as each other. As shown in FIG. 2, when lever 2 and base 4 are assembled with each other, cylindrical portion 44 and partial cylindrical portion 25 are assembled so that they may be arranged substantially concentrically and so that partial cylindrical portion 25 may be arranged above cylindrical portion 44.

In addition, inner surfaces of cylindrical portion 44 and partial cylindrical portion 25 are formed smoothly. Rod-like male screw portion 51 is provided at foot 5, and male screw portion 51 is inserted through cylindrical portion 44 of base 4 and partial cylindrical portion 25 of lever 2. Cylindrical portion 44 of base 4 guides a protruding direction of inserted foot 5. In addition, supporting portion 52 is provided at a lower end of foot 5.

A thread is formed at foot 5 along a longitudinal direction thereof to serve as male screw portion 51. Female screw portion 26 that engages with male screw portion 51 is provided at a part of lever 2.

The thread of male screw portion 51 and a thread of female screw portion 26 are engaged with each other in a state shown in FIG. 2. Accordingly, foot 5 is fixed to base 4.

It is to be noted that a configuration in which the threads are formed at male screw portion 51 of foot 5 and female screw portion 26 of lever 2 is not essential. If concave-convex surfaces that can engage with each other in a vertical direction are formed at foot 5 and lever 2, respectively, it is possible for lever 2 to fix foot 5 to base 4.

Lever 2 can be rotated in tilt foot mechanism 1. Here, a rotation of the direction of arrow f, as a first direction, is defined as a forward rotation, and the rotation of the direction of arrow e, as a second direction is defined as a backward rotation.

Operating portion 21 used for a rotating operation is provided at lever 2. Operating portion 21 is plate-shaped, and extends forward from the center of lever 2.

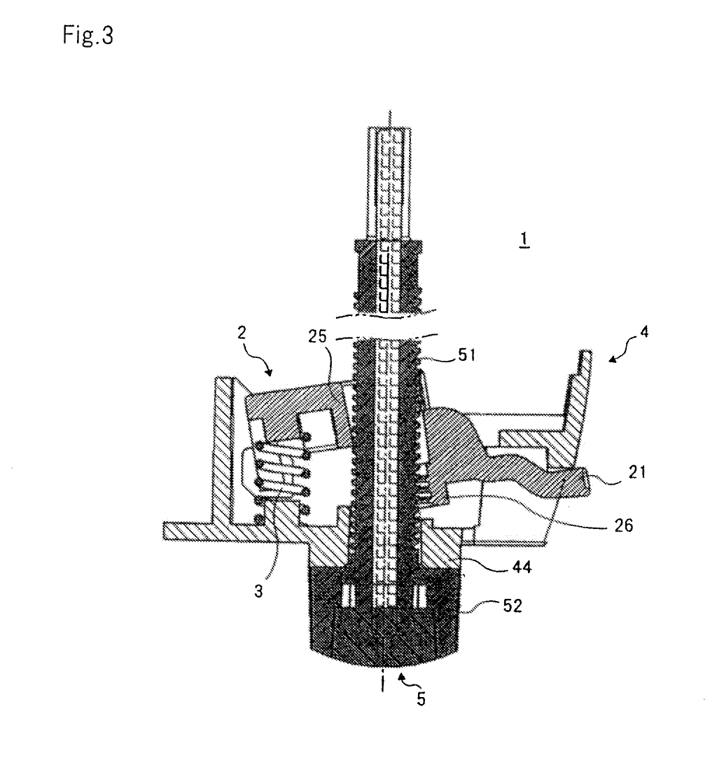

FIG. 3 is a view showing a state where operating portion 21 is pressed from the state shown in FIG. 2, and lever 2 is rotated backward.

In the state shown in FIG. 3, female screw portion 26 of lever 21 is spaced apart from male screw portion 51 of foot 5. Accordingly, foot 5 can be moved in the longitudinal direction of male screw portion 51 with respect to base 4. In this state, the length of the protruding portion of foot 5 is changed.

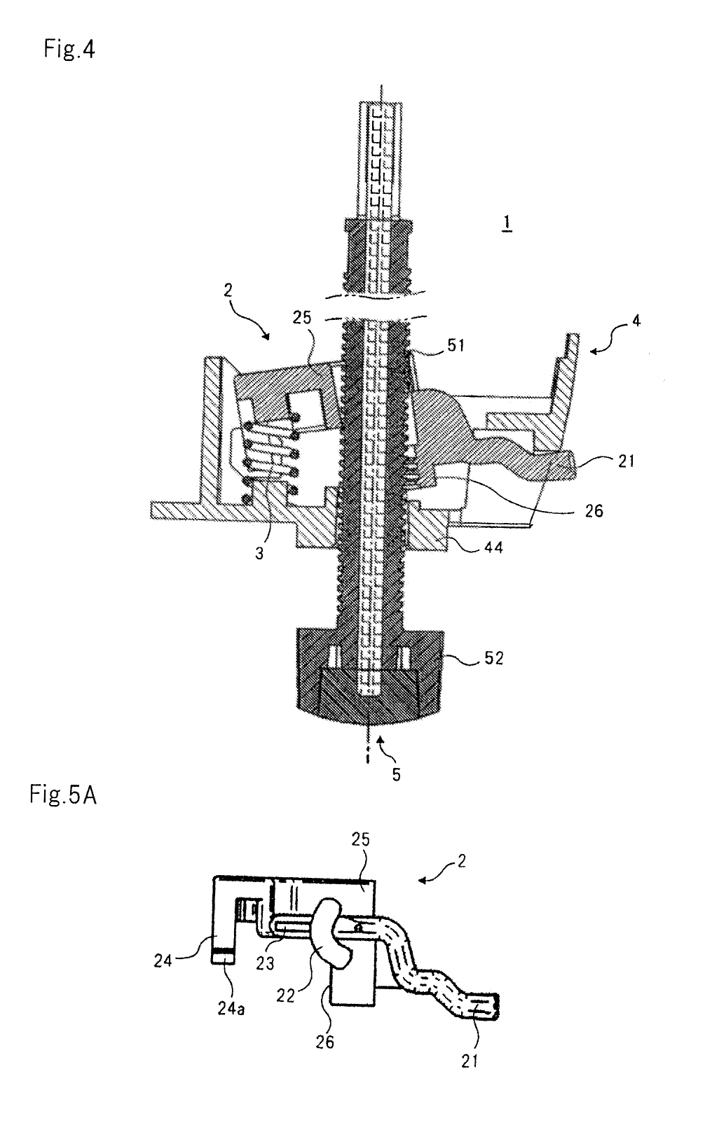

FIG. 4 shows a state where the length of the protruding portion of foot 5 is changed from the state shown in FIG. 3. Spring 3 held between base 4 and lever 2 is provided at the rear of base 4 and lever 2. Spring 3 is a biasing member that biases lever 2 so that lever 2 may rotate forward.

Spring 3 is pressed by base 4 and lever 2 to be elastically deformed in the state where lever 2 shown in FIGS. 3 and 4 has been rotated backward. Accordingly, spring 3 biases lever 2 so that lever 2 may rotate forward. Therefore, when the press to operating portion 21 is released, lever 2 is rotated forward by an elastic force of spring 3, and female screw portion 26 of lever 2 is pressed to make contact with male screw portion 51 of foot 5. As a result, foot 5 is fixed to base 4 again.

As described above, it is possible to change the length of the protruding portion of foot 5 to an arbitrary length in tilt foot mechanism 1. Further, since foot 5 has been fixed to base 4 by engagement of the thread of male screw portion 51 and the thread of female screw portion 26 in tilt foot mechanism 1, it is also possible for foot 5 to be rotated in a circumferential direction and thereby the length of the protruding portion of foot 5 can be finely adjusted.

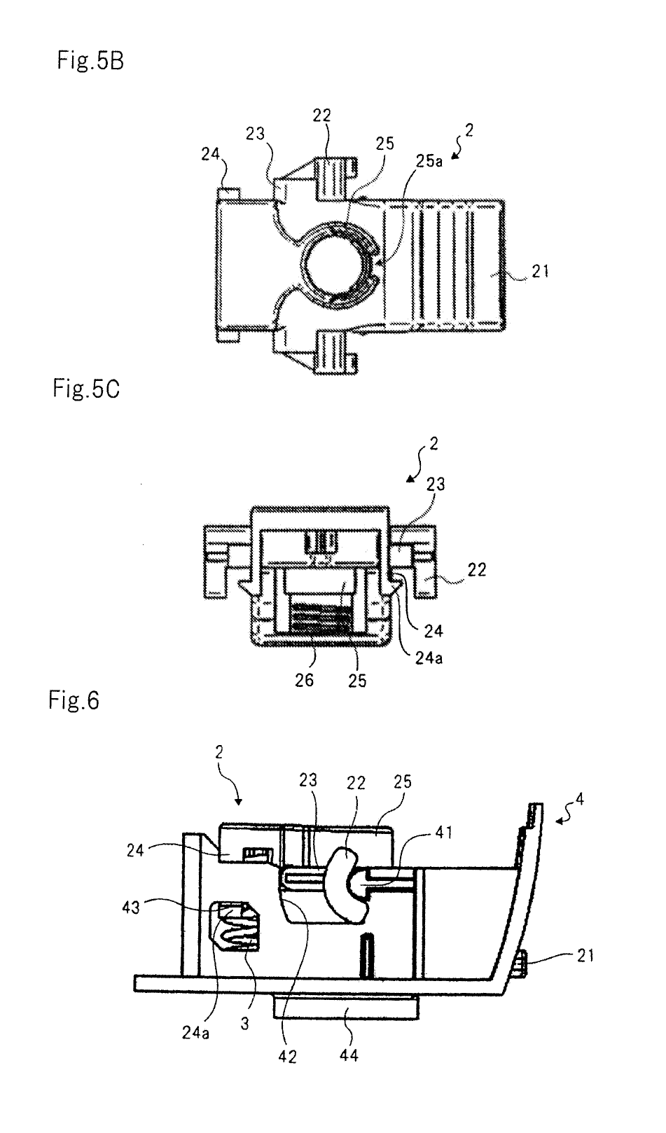

FIGS. 5A to 5C show lever 2, and FIG. 5A is aside view, FIG. 58 is a top view, and FIG. 5C is a rear view. Lever 2 includes bearing portion 22 provided at both side surfaces in the center of a front-rear direction, and projecting portion 23 that extends backward from each bearing portion 22.

Operating portion 21 is plate-shaped, and extends forward from partial cylindrical portion 25 of lever 2. A front surface of bearing portion 22 is processed into a circularly hollow shape. In addition, the tip of projecting portion 23 is processed into a curved surface. Details of the shape of the tip of projecting portion 23 will be described hereinafter.

Notch portion 25a is formed at the front side of partial cylindrical portion 25 of lever 2. Accordingly, partial cylindrical portion 25 has a C shape as shown in FIG. 2B when viewed from the top. As a result, even though lever 2 is rotated backward as shown in FIGS. 3 and 4, male screw portion 51 does not make contact with partial cylindrical portion 25 of lever 2.

Elastic piece 24 extending downward is provided at both side ends of the rear end of lever 2. Engaging portion 24a protruding outward is formed at the lower end of elastic piece 24. Elastic piece 24 is formed thin, and is elastically deformed when subjected to a force from the side.

FIG. 6 is a side view showing a state where lever 2 and spring 3 are attached to base 4. Spring 3 is arranged upright at the rear of base 4.

Shaft portion 41 and guiding surface 42 opposed to each other are provided at base 4. A back surface of shaft portion 41 is formed circular, and is in surface contact with a front surface of bearing portion 22. In addition, guiding surface 42 is formed concentrically with shaft portion 41, and guiding surface 42 is in line contact with the tip of projecting portion 23.

As described above, bearing portion 22 and projecting portion 23 are held between shaft portion 41 of base 4 and guiding surface 42, and thereby lever 2 is held by base 4. In addition, the central axis of shaft portion 41 and guiding surface 42 defines the rotation center of lever 2, and functions as a rotating shaft when lever 2 rotates with respect to base 4.

When operating portion 21 is pressed and lever 2 is rotated backward, bearing portion 22 slides along shaft portion 41, and projecting portion 23 slides downward along guiding surface 42. Accordingly, when lever 2 rotates, contact between bearing portion 22 and shaft portion 41 is maintained, and contact between projecting portion 23 and guiding surface 42 is also maintained. It is defined that “contact” described here includes a state of being spaced apart from each other to an extent that a smooth rotation of lever 2 is not prevented.

As described above, when lever 2 is rotated, a back surface of shaft portion 41 opposed to guiding surface 42 functions as a first guiding portion that guides bearing portion 22, which is a first guided portion, and guiding surface 42 functions as a second guiding portion that guides projecting portion 23, which is a second guided portion.

Spring 3 is pressed by base 4 and lever 2 to also be elastically deformed in a state shown in FIG. 6. Accordingly, spring 3 tends to rotate lever 2 forward by the elastic force. When lever 2 rotates forward and projecting portion 23 moves upward to get out of guiding surface 42, lever 2 is detached from base 4.

In order to prevent the above situation, tilt foot mechanism 1 according to the exemplary embodiment includes a mechanism to limit the forward rotation of lever 2. The mechanism comprises elastic piece 24 of the lever 2 described above and engaging surface 43 provided at the rear of base 4. Engaging portion 24a of elastic piece 24 is engaged from a lower side with engaging surface 43 of base 4. Therefore, lever 2 is not rotated forward more than the state shown in FIG. 3, and thus the state where lever 2 and base 3 are assembled with each other is maintained.

When lever 2 is attached to base 4, first, spring 3 is arranged upright at the rear of base 4. Next, operating portion 21 is inserted in base 4 at an angle in which lever 2 is inclined forward, and bearing portion 22 is made to come into between contact with shaft portion 41. Additionally, when lever 2 is rotated backward while contact of bearing portion 22 and shaft portion 41 is kept, engaging portion 24a of elastic piece 24 comes into contact with the upper part of base 4. When lever 2 is further rotated, elastic piece 24 is elastically deformed inward, and engaging portion 24a slides downward along the inner surface of base 4.

When lever 2 is further rotated, the tip of projecting portion 23 enters guiding surface 42. At this time, lever 2 is in contact with the top end of spring 3. Accordingly, subsequently, lever 2 is rotated while pressing spring 3 to be elastically deformed. Along with this rotation, the tip of projecting portion 23 slides along guiding surface 42. Lever 2 is rotated backward until it achieves a horizontal angle. At that time, engaging portion 24a is engaged with engaging surface 43 just before lever 2 achieves the horizontal angle.

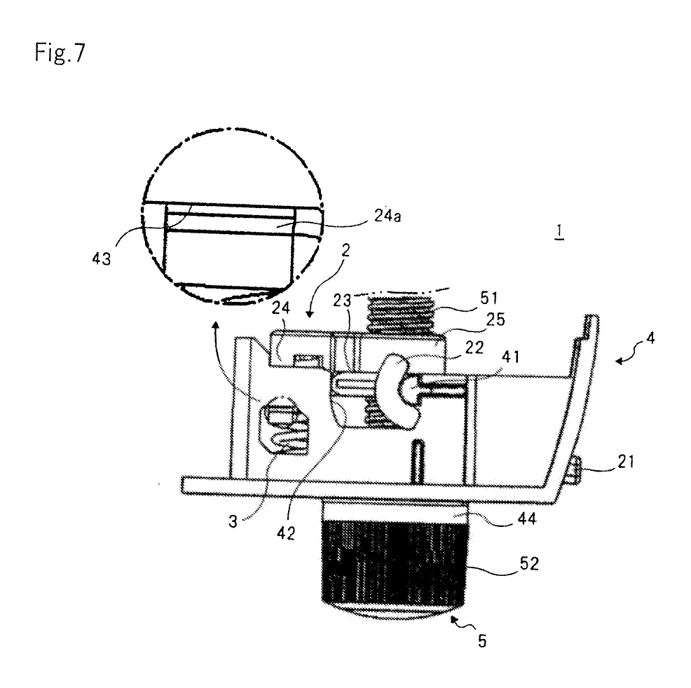

FIG. 7 is a side view showing the state where foot 5 is attached to base 4 to which lever 2 and spring 3 are attached shown in FIG. 6. When foot 5 is attached from the state shown in FIG. 6, first, lever 2 is rotated backward and female screw portion 26 shown in FIG. 2 is moved forward. In this state, male screw portion 51 of foot 5 is inserted from a lower side through cylindrical portion 44 of base 4 and partial cylindrical portion 25 of lever 2.

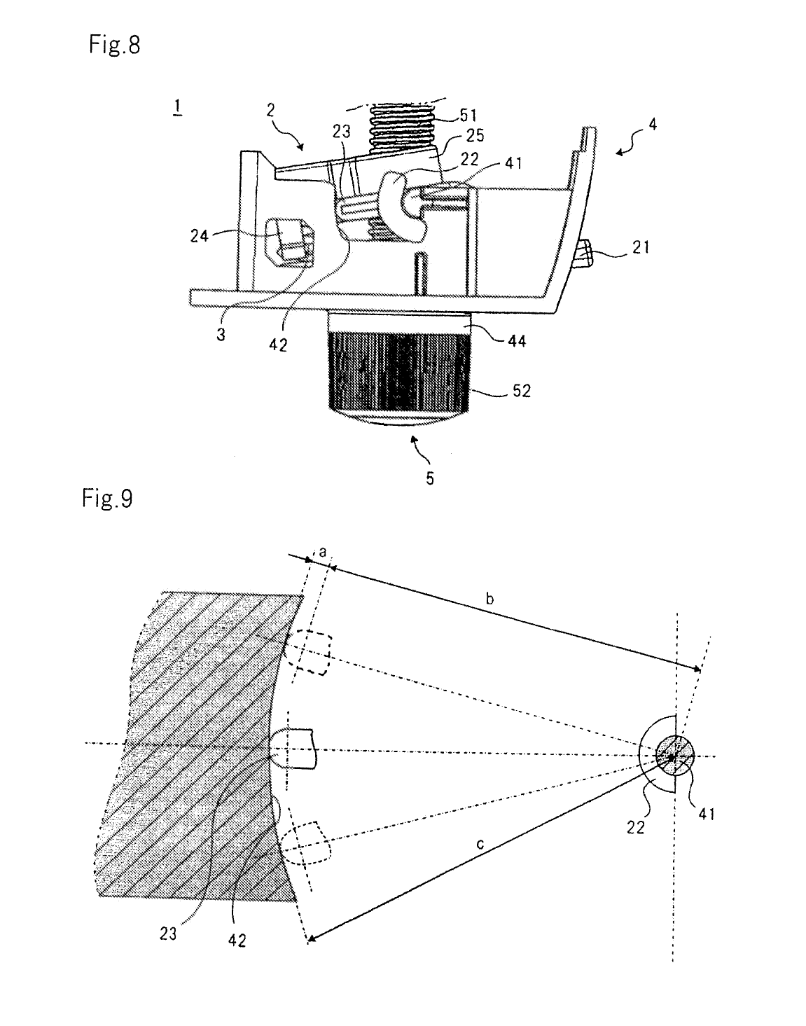

A state is shown in FIG. 8 where male screw portion 51 of foot 5 is inserted through cylindrical portion 44 of base 4 and partial cylindrical portion 25 of lever 2. In this state, as shown in FIG. 3, female screw portion 26 has been moved forward, and thus female screw portion 26 is prevented from being an obstacle when foot 5 is inserted through base 4 and lever 2. Subsequently, when depressed operating portion 21 is released, lever 2 is rotated forward by the elastic force of spring 3, and changes to a state in which it is at the horizontal angle as shown in FIG. 7.

As described above, tilt foot mechanism 1 is assembled. As mentioned above, a supporting member for keeping a lever from being detached from a base is provided in a general tilt foot mechanism. However, lever 2 is not detached from base 4 in tilt foot mechanism 1 even without such a supporting member. Accordingly, the number of parts is decreased in tilt foot mechanism 1. In addition, tilt foot mechanism I can be easily assembled without using a tool etc. Accordingly, a reduction in manufacturing cost can be achieved.

It is to be noted that in the state where foot 5 is attached, engaging portion 24a of elastic piece 24 is slightly spaced apart downwardly from engaging surface 43 as shown in an upper-left enlarged view of FIG. 7. Usually, foot 5 is kept to be attached to tilt foot mechanism 1, and thus much load is not applied to elastic piece 24. Accordingly, elastic piece 24 is hard to be damaged.

Next will be described the shape of the tip of projecting portion 23 of tilt foot mechanism 1 according to the exemplary embodiment with reference to FIG. 9. For convenience in description, shaft portion 41, bearing portion 22, projecting portion 23, and guiding surface 42 are simplified shown as in FIG. 9. Namely, shaft portion 41 is shown as a cylinder, and bearing portion 22 is shown as a semicylinder. Further, only the tip is shown in projecting portion 23, and the portion between the tip of projecting portion 23 and bearing portion 22 is omitted.

A side cross section of the tip of projecting portion 23 is formed so as to be a semicircle with radius a. Accordingly, given that the distance from the central axis of shaft portion 41 serving as the rotating shaft of projecting portion 23 to the tip of projecting portion 23 is set to be b, and that the radius of guiding surface 42 is set to be c, the relation “c=a+b” is established. Since radius a of the tip of projecting portion 23 is smaller than radius c of guiding surface 42, the tip of projecting portion 23 is in line contact with guiding surface 42.

It is to be noted that the shape of the cross section of the tip of projecting portion 23 is not limited to a circle, and that it may be a shape whose radius of curvature is smaller than radius c of guiding surface 42 and with which the tip of projecting portion 23 makes line contact with guiding surface 42.

However, it is desirable that the line that connects the central axis of shaft portion 41 and a portion where the tip of projecting portion 23 is in contact with guiding surface 42 correspond to a normal line to guiding surface 42 as shown in FIG. 9. When configured, as described above, a force is uniformly added from guiding surface 42 to projecting portion 23, thus allowing projecting portion 23 to slide more smoothly along guiding surface 42.

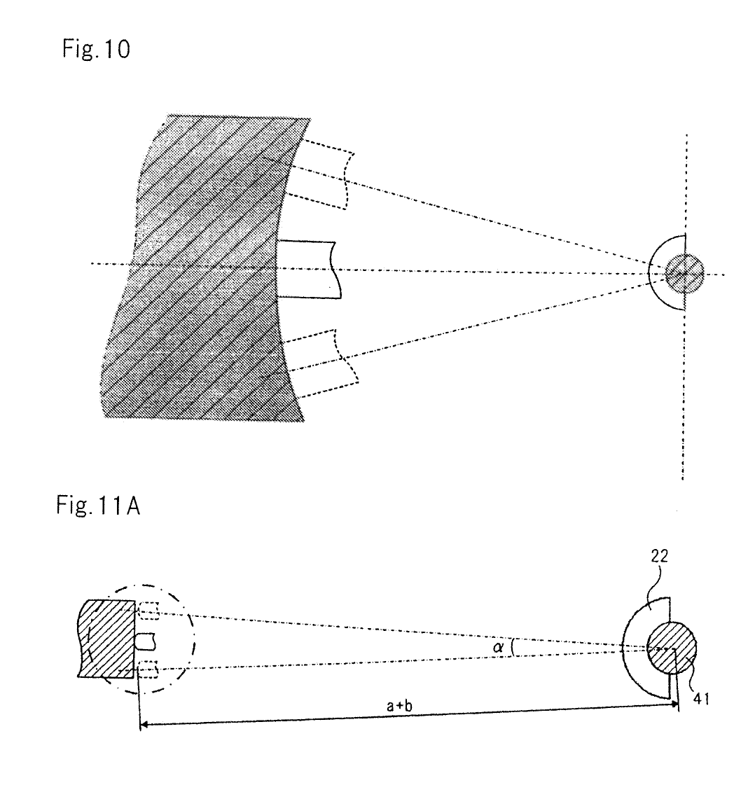

In addition, as shown in FIG. 10, the radius of the tip of the projecting portion may be equal to the radius of the guiding surface. In this case, since the tip of the projecting portion makes surface contact with the guiding surface, the tip of the projecting portion can slide more stably along the guiding surface. On the other hand, frictional resistance, when the tip of the projecting portion slides along the guiding surface, is increased.

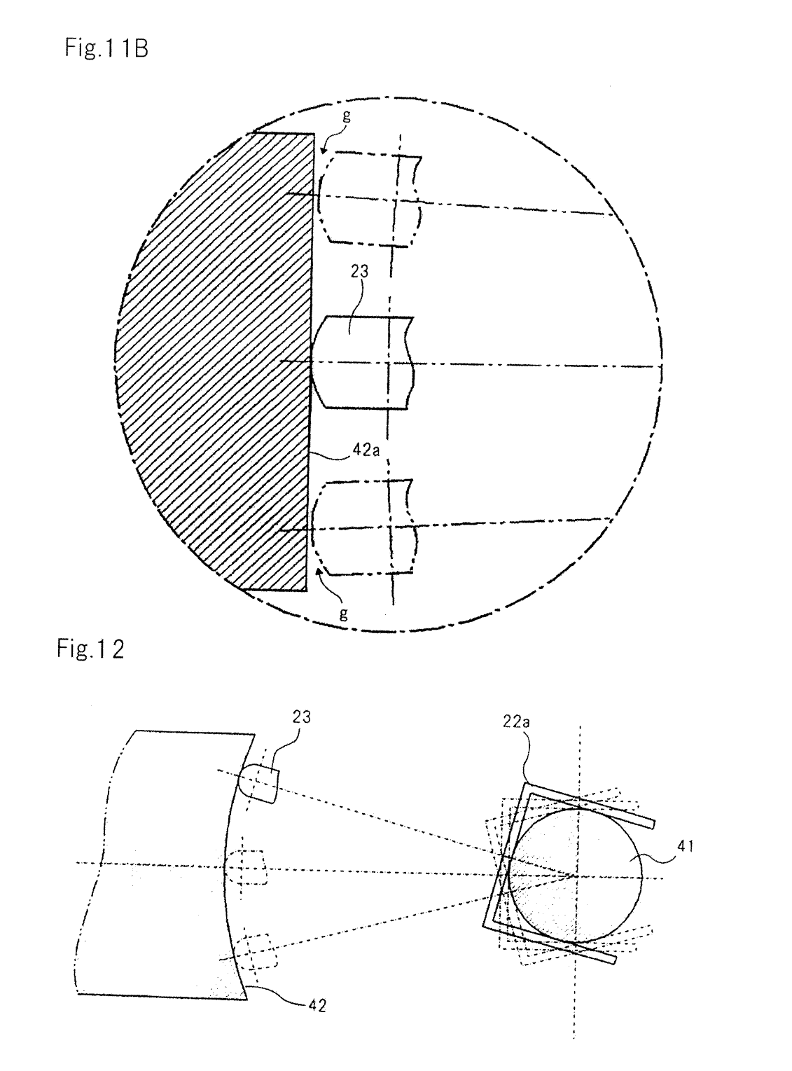

In addition, when maximum rotation angle a, which is the upper limit of the angle to which bearing portion 22 is rotated with respect to shaft portion 41, is small as shown in FIG. 11A, there is a case where the guiding surface may be a flat surface. FIG. 11B is an enlarged view of a portion enclosed with an alternate long and short dash line of FIG. 11A. Guiding surface 42a is the flat surface. When bearing portion 22 is rotated with respect to shaft portion 41, gap g is formed between projecting portion 23 and guiding surface 42a as shown in FIG. 11B. When this gap g is large, rotation of bearing portion 22 with respect to shaft portion 41 becomes unstable.

However, for example, given that a+b is set to be 21 mm and the maximum rotation angle α is 6 degrees, the size of gap g is less than 0.03 mm. The product tolerance of each part comprising the tilt foot mechanism is several times as large as 0.03 mm. Accordingly, in this case, projecting portion 23 and guiding surface 42a are considered to be in contact with each other, and even though guiding surface 42a is the flat surface, smooth rotation of lever 2 is not prevented. If guiding surface 42a is the flat surface, manufacturing cost will be reduced due to easy processing.

In addition, although the configuration in which shaft portion 41 and bearing portion 22 make surface contact with each other is employed in all the configurations shown in FIGS. 9 to 11A, such a configuration is not essential. For example, as shown in FIG. 12, bearing portion 22a formed as a rectangle may be arranged so as to surround shaft portion 41 from an upper side, a rear, and a lower side thereof.

In this case, bearing portion 22a is in line contact with shaft portion 41 at three points, i.e., an upper part, a rear, and a lower part thereof, and thus shaft portion 41 is stably held in bearing portion 22a. In addition, since contact of bearing portion 22a with shaft portion 41 is a line contact, frictional resistance is reduced when bearing portion 22a rotates with respect to shaft portion 41.

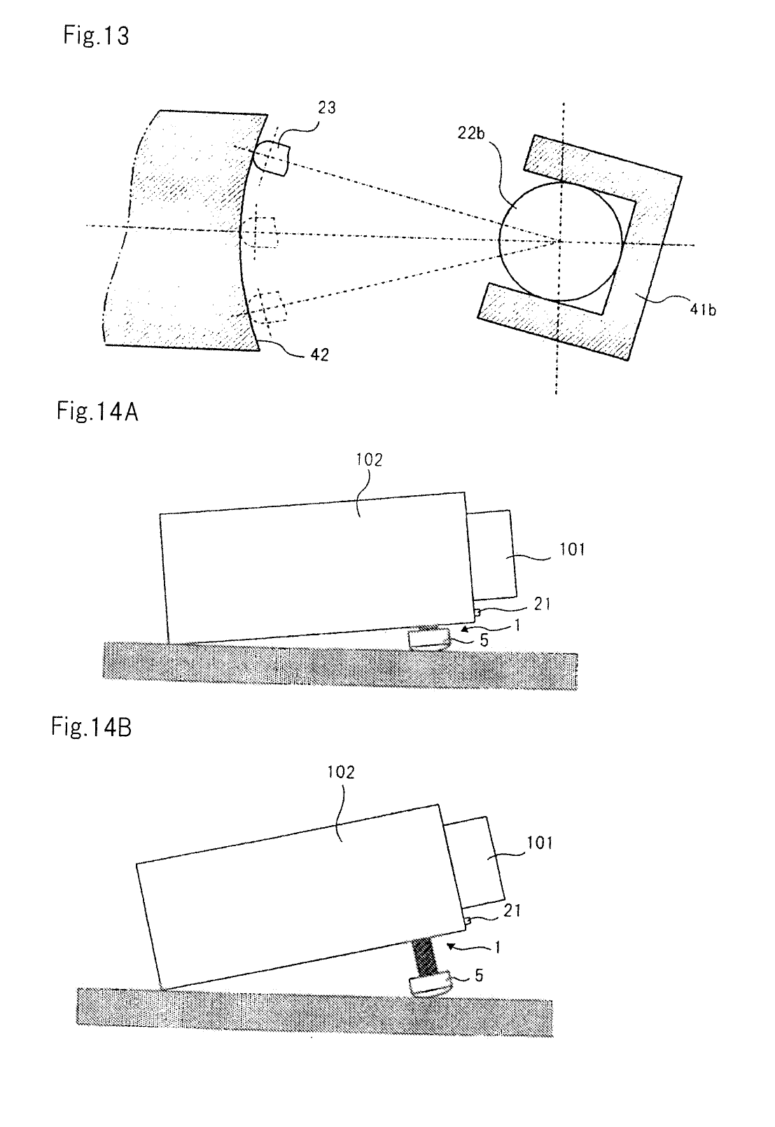

In addition, the shaft portion and the bearing portion may be provided conversely. Namely, the shaft portion may be provided at the lever, and the bearing portion may be provided at the base. One example of such a configuration is shown in FIG. 13. In this configuration, cylindrical shaft portion 22b is surrounded by bearing portion 41b formed as a rectangle from the upper side, the front, and the lower side.

Accordingly, shaft portion 22b is housed in bearing portion 41b, and shaft portion 22b and projecting portion 23 are held between bearing portion 41b and guiding surface 42. In this case, the rotating shaft, when the lever is rotated with respect to the base, functions as a central axis of shaft portion 22b.

FIGS. 14A and 14B are side views of a projection display to which tilt foot mechanism 1 according to the exemplary embodiment is applied. Tilt foot mechanism 1 is provided at the bottom surface of case 102. Base 4 shown in FIG. 1 is formed integrally with case 102.

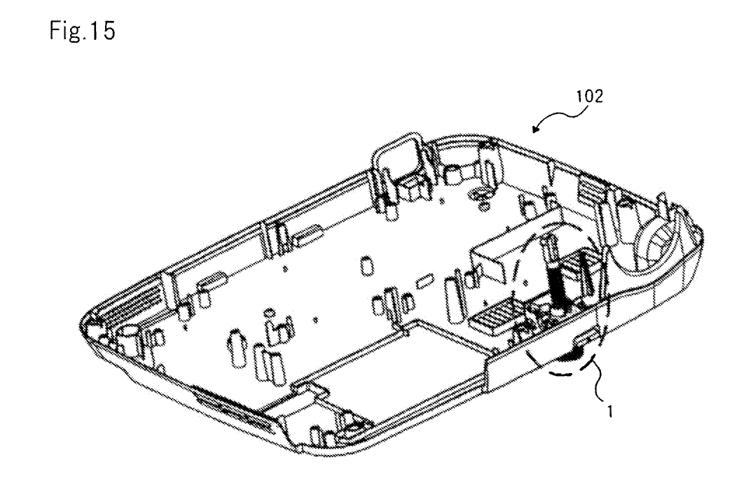

FIG. 15 is a perspective view showing tilt foot mechanism 1 and the lower part of case 102 after the projection display shown in FIGS. 14A and 14B is disassembled. FIG. 15 shows the inside of case 102 viewed from the upper side. The portion of foot 5 above base 4 and lever 2 is housed in case 102.

When operating portion 21 is pressed up upwardly, the length of the protruding portion of foot 5 can be changed, and the state of the projection display shown in FIG. 14A is, for example, changed to a state shown in FIG. 14B. As a result, the tilt angle of case 102 changes and a direction of projection lens 101 changes, thus a resulting in a change of the projection angle of this projection display. As described above, the projection angle can be changed easily in this projection display.

Although the invention in this application has been described with reference to the exemplary embodiment as described above, the invention in this application is not limited to the above exemplary embodiment. Various changes that those skilled in the art can understand can be made to the configurations and details of the invention in this application within the scope of the invention in this application.

### REFERENCE SIGNS LIST

1 Tilt Foot Mechanism
2 Lever
3 Spring
4 Base
5 Foot
21 Operating Portion
22 Bearing Portion
23 Projecting Portion
24 Elastic Piece
24a Engaging portion
25 Partial Cylindrical Portion
26 Female Screw Portion
41 Shaft Portion
42 Guiding Surface
43 Engaging Surface
44 Cylindrical Portion
51 Male Screw Portion
52 Supporting Portion

1. A tilt foot mechanism that adjusts a tilt angle of a case by adjusting a length of a protruding portion of a foot protruding from said case, the tilt foot mechanism comprising:
a base into which said foot is inserted, wherein said base guides a protruding direction of said inserted foot; and
a lever that is assembled with said base and that fixes said foot to said base by being biased to said foot, wherein said lever is rotatable, and said lever is maintained in a state of fixing said foot by a biasing force in a first direction, and said lever releases fixing of said foot by being rotated in a second direction which is different from said first direction, wherein
a first guiding portion and a second guiding portion are provided at said base, wherein said first guiding portion and said second guiding portion define a rotation center of said lever when said first guiding portion and said second guiding portion are assembled with said base, and
a first guided portion, a second guided portion, and an engaging portion are provided at said lever, wherein said first guided portion and said second guided portion slide along said first guiding portion and said second guiding portion, and wherein said engaging portion remains in a state of being assembled with said base.

2. The tilt foot mechanism according to claim 1, wherein the tilt foot mechanism comprises a spring that generates the biasing force of the first direction.

3. The tilt foot mechanism according to claim 1, wherein a thread is formed at each contact portion of each of said foot and said lever, and wherein each thread is engaged with each other when said lever is biased to said foot to be in contact with each other.

4. The tilt foot mechanism according to claim 1, wherein contact of said first guiding portion and said first guided portion comprises line contact, or contact of said second guiding portion and said second guided portion comprises line contact, or said contact of said first guiding portion and said first guided portion and said contact of said second guiding portion and said second guided portion comprise contact.

5. A projection display, wherein the tilt foot mechanism according to claim 1 is provided at a bottom surface of a case.

6. The projection display according to claim 5, wherein said base of said tilt foot mechanism is formed integrally with said case.

7. The tilt foot mechanism according to claim 2, wherein a thread is formed at each contact portion of each of said foot and said lever, and wherein each thread is engaged with each other when said lever is biased to said foot to be in contact with each other.

8. The tilt foot mechanism according to claim 2, wherein contact of said first guiding portion and said first guided portion comprises line contact, or contact of said second guiding portion and said second guided portion comprises line contact, or said contact of said first guiding portion and said first guided portion and said contact of said second guiding portion and said second guided portion comprise line contact.

9. The tilt foot mechanism according to claim 3, wherein contact of said first guiding portion and said first guided portion comprises line contact, or contact of said second guiding portion and said second guided portion is line contact, or said contact of said first guiding portion and said first guided portion and said contact of said second guiding portion and said second guided portion comprise line contact.

10. A projection display, wherein the tilt foot mechanism according to claim 2 is provided at a bottom surface of a case.

11. A projection display, wherein the tilt foot mechanism according to claim 3 is provided at a bottom surface of a case.

12. A projection display, wherein the tilt foot mechanism according to claim 4 is provided at a bottom surface of a case.
